(19) United States
(12) Patent Application Publication
(10) Pub. No.: US 2007/0298531 A1
(43) Pub. Date: Dec. 27, 2007

(54) Quantum Well Intermixing in Semiconductor Photonic Devices

(76) Inventor: Stephen Najda, Glasgow (GB)

Correspondence Address: MOMKUS MCCLUSKEY MONROE MARSH & SPYRATOS, LLC, 3051 OAK GROVE ROAD, SUITE 220, DOWNERS GROVE, IL, 60515-1181, US

(21) Appl. No.: 10/533,330

(22) PCT Filed: Oct. 30, 2003
(86) PCT No.: PCT/GB03/04705

§ 371 Date: Mar. 31, 2006

(30) Foreign Application Priority Data
Nov. 2, 2002 (GB) 0225586.7

(51) Int. Cl. H01S 5/34; H01L 21/18

(52) U.S. Cl. 438/47; 257/E21.086

(57) ABSTRACT

A method for fabricating a semiconductor device in a semiconductor structure, provides enhanced quantum well intermixing in desired regions of the device by forming a first, relatively high quality, epitaxial layer on a substrate, the high quality layer including a quantum well; forming a second, relatively lower quality, epitaxial defect layer on top of the high quality layer, and thermally processing the structure to effect at least partial diffusion of the defects from the defect layer into the high quality layer in order to achieve quantum well intermixing in the structure. The use of an epitaxially grown defect layer on top of, or within, a high quality epitaxially grown device body enables quantum well intermixing techniques to be performed at lower temperatures and thereby improves device characteristics.

The present invention relates to quantum well intermixing methods for application in the manufacture of semiconductor photonic devices and in the integration of such devices onto a semiconductor substrate.

Impurity free intermixing allows the band-gap of a semiconductor quantum well structure to be locally increased in a controlled manner thereby allowing both active and passive components to be fabricated on semiconductor substrate to improve the performance of individual photonic devices. This also facilitates large scale photonic integration.

Quantum Well Intermixing (QWI) has been developed as a technique to controllably increase the band-gap of a semiconductor quantum well (QW) structure. The intermixing modifies the band-gap of QW structures. For example, a GaAs QW with AlGaAs barriers may be intermixed to give rise to a parabolic well that is ‘blue-shifted’ with respect to the QW. Intermixing is spatially selective, allowing the fabrication of individual photonic devices or photonic integrated circuits with passive and active regions.

A number of intermixing techniques have been reported, most notably impurity induced disordering (IID), laser induced disordering and dielectric cap annealing.

Quantum well intermixing by impurity induced disordering requires that impurities are introduced into the semiconductor either by diffusion from the surface or by ion implantation. The disadvantage of using impurity induced disordering is that the impurities introduced to disorder the crystal also provide light absorption and scattering centres, and are hence undesirable.

For a discussion of impurity diffusion techniques, see V W D Laidig et al, Appl Phys Lett, Vol 38, p776-778, 1981. For a discussion of ion-implantation techniques, see J P Noel et al, Appl Phys Lett, Vol 69, p3516-3518, 1996.

The other intermixing techniques do not involve introducing impurities into the crystal, however laser induced disordering is a difficult process to control in a manufacturing environment since it produces non-uniformity across the intermixed regions. For a discussion, of photoabsorption, see A. McKee et al, IEEE J of Quantum Electronics, Vol 33, p45-55, 1997.

Etch and selective regrowth can also provide a method for achieving multiple band-gap material, but this technique is difficult and expensive. See T M Cockerill et al, IEEE Photonics Technology Letter, Vol 6, p786-788, 1994.

Dielectric cap annealing provides a way forward for a manufacturable ‘impurity-free’ intermixing process, see J H Marsh et al, PCT/GBO2/00292 and PCT/GBO2/00445. However, a very high temperature anneal is required to get sufficient intermixing, which can give rise to contact problems and diffusion of impurities. The processes consider depositing a dielectric cap, such as silica, on top of the semiconductor surface. During the sputtering process, point defects are generated on the surface of the semiconductor. A thermal anneal results in the out-diffusion of Ga from the epilayer into the dielectric cap. The out-diffusion results in the intermixing of the QW region and hence a band gap increase. The disadvantage with this process is that it can be difficult to control and requires expensive processing equipment.

A semiconductor laser capped with a low temperature layer to enhance the QWI has been proposed by A S W Lee et at, Appl Phys Lett, 78, 21, p3199 (2001) and A S W Lee et al, Semicond Sci Tech, 15, 12, L41, (2000). However, a significant temperature change during growth may enhance the intermixing, but often leads to a deleterious effect on the laser performance.

It is therefore an object of the present invention to provide an impurity free intermixing technique that has a low anneal temperature, that is simple to fabricate, and that is easier and cheaper to manufacture.

According to one aspect, the present invention provides a method of fabricating a semiconductor device in a semiconductor structure, comprising the steps of:
forming a first, relatively high quality, epitaxial layer on a substrate, the high quality layer including a quantum well;
forming a second, relatively lower quality, epitaxial defect layer on top of the high quality layer; and
thermally processing the structure to effect at least partial diffusion of the defects from the defect layer into the high quality layer in order to achieve quantum well intermixing in the structure.

Embodiments of the present invention will now be described by way of example and with reference to the accompanying drawings in which:

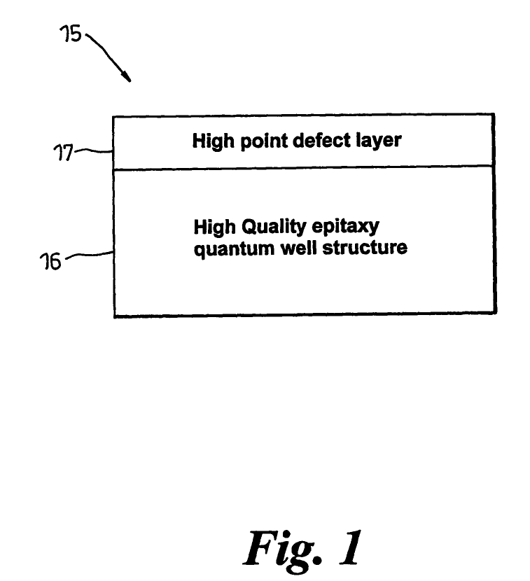

FIG. 1 shows a schematic diagram of an epitaxy structure with a high defect density layer grown on top;

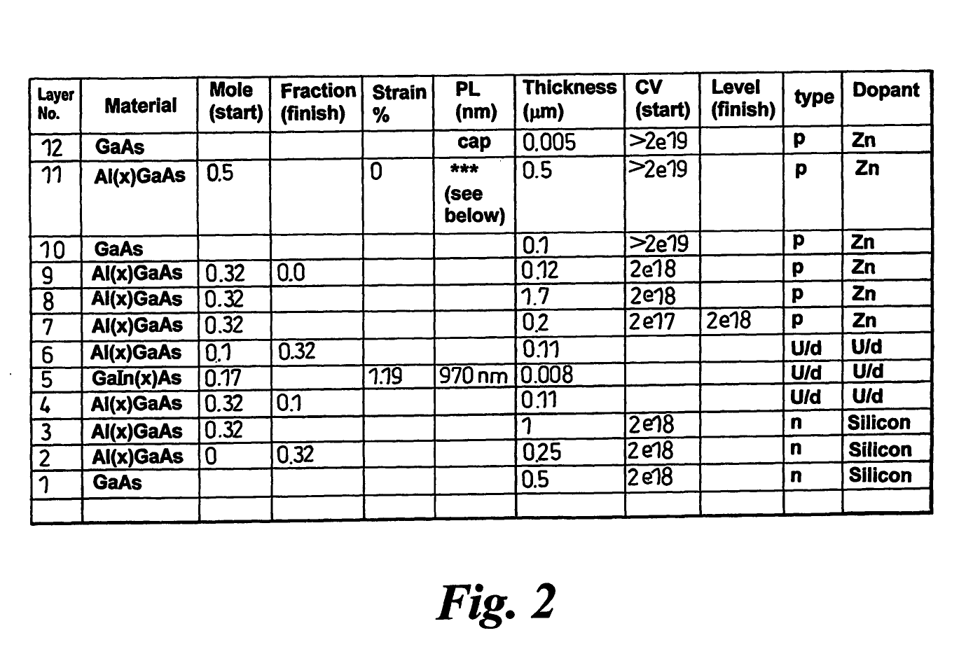

FIG. 2 shows the layered structure for a 980 nm laser with a high defect density AlGaAs upper layer;

FIG. 3 shows a schematic diagram of the epitaxy structure of FIG. 1 after photolithography and etching for manufacture of a semiconductor laser;

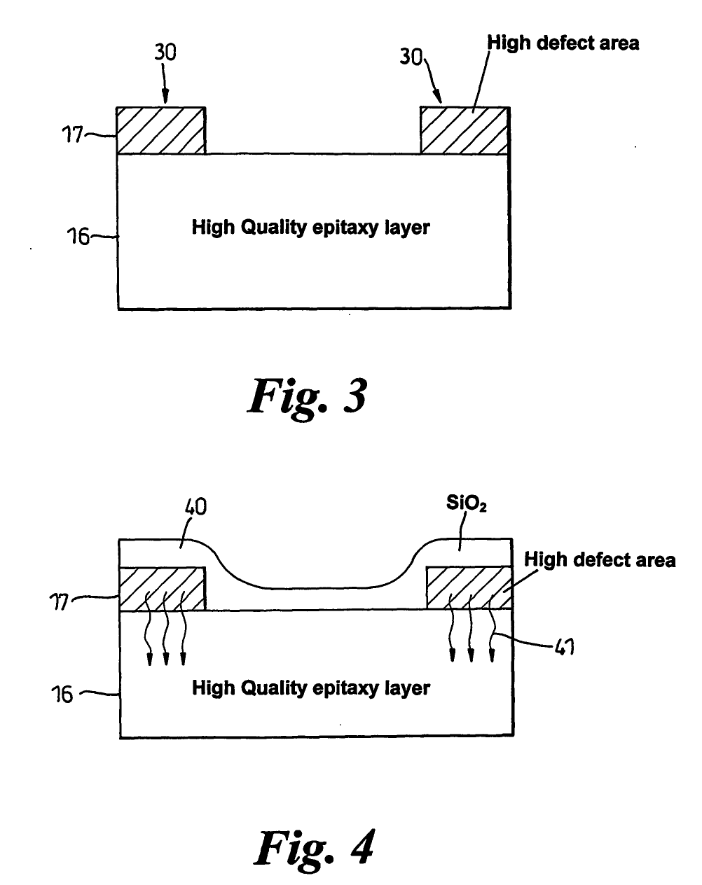

FIG. 4 shows a schematic diagram of the epitaxy structure of FIG. 3 after deposition of a layer of silica and during thermal anneal;

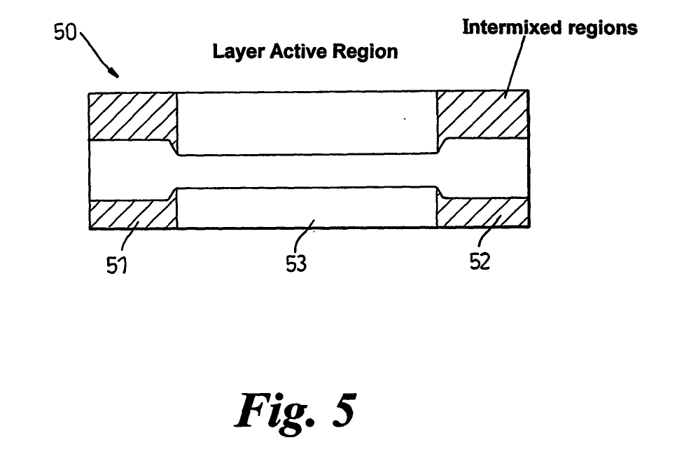

FIG. 5 shows a band gap diagram of the resulting laser structure with intermixed facet regions;

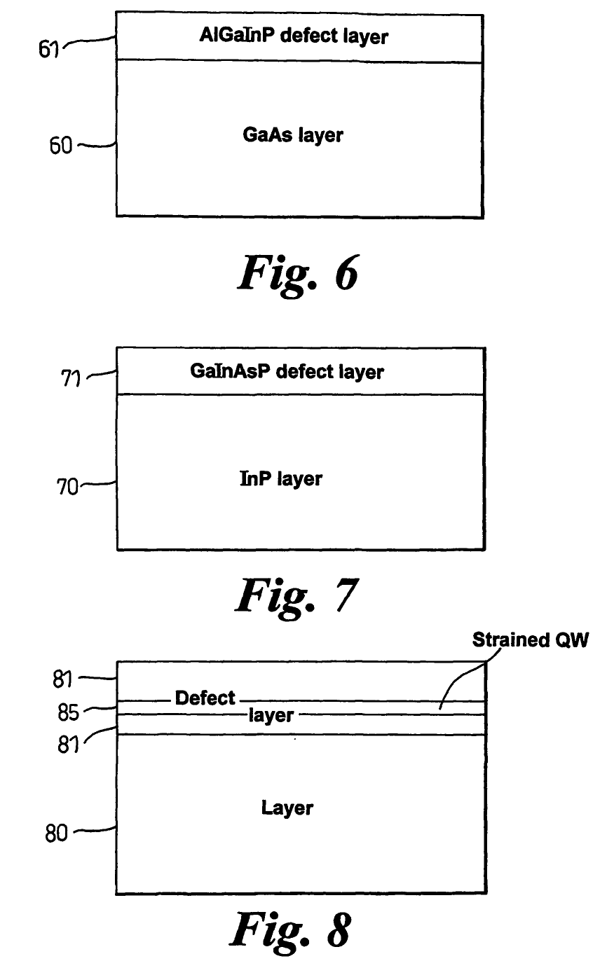

FIG. 6 shows schematic diagram of a epitaxy structure having a high defect AlGaInP layer as a strain layer;

FIG. 7 shows a schematic diagram of an InP based epitaxy structure having high defect density layer of GaInAsP grown on top;

FIG. 8 shows a schematic diagram of an epitaxy structure having a high defect density layer grown with a strained QW;

FIG. 9 shows a schematic diagram of an epitaxy structure with a patterned surface and semiconductor material is grown on top;

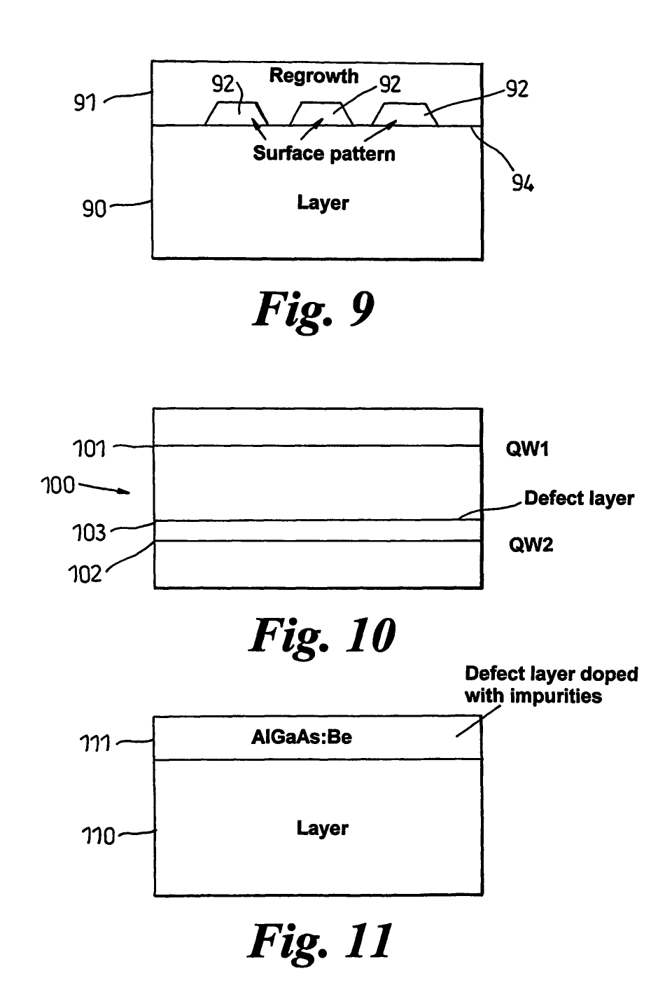

FIG. 10 shows a schematic diagram of a double QW system having a defect layer located close to the QW nearer to the substrate;

FIG. 11 shows a schematic diagram of an epitaxy structure having a high defect density layer that is doped with an impurity grown on top; and

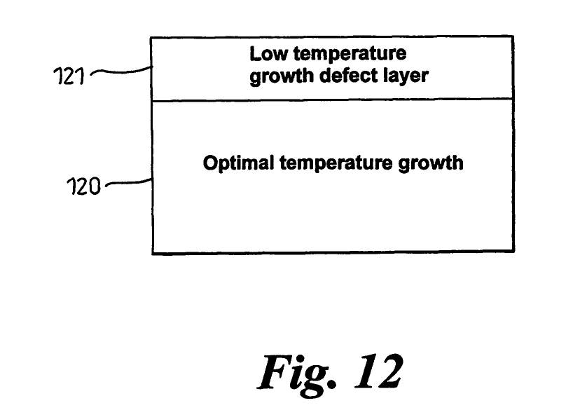

FIG. 12 is a schematic diagram of an epitaxy structure having a high defect density layer grown by significantly lowering the growth temperature to allow intermixing to occur.

The present invention proposes introducing a high defect layer into a semiconductor structure during epitaxial growth of the substrate such that the wafer can be easily intermixed by a straightforward and relatively low temperature annealing process.

The intermixing technique of the present invention can be applied to any III-V or II-VI semiconductor structures, such as GaAs/AlGaAs, GaInP/AlGaInP, InGaAs/InGaAsP, InGaAs/InAlGaAs and the like. An example of a 980 nm InGaAs/AlGaInAs laser with passive intermixed regions near the facet is described by way of example.

The invention has application in at least the fabrication of semiconductor lasers, vertical cavity light emitting devices, semiconductor optical integration, semiconductor passive waveguides, optoelectronic integrated circuits and photonic integrated circuits.

High quality, epitaxy semiconductor crystal growth requires the source element III-V ratio, substrate temperature, and other crystal growth parameters to be optimised to obtain sufficient quality material to fabricate high performance photonic devices. Growth conditions outside this ‘window’ of growth parameters can give rise to crystalline defects that degrade the performance of the device. Therefore, during conventional epitaxial growth of semiconductor device materials, very careful attention is paid to the maintenance of the correct growth parameters.

The present invention proposes the growth of high quality semiconductor QW structures, such as a QW laser for example, under these optimum growth conditions, but with the deliberate introduction of a ‘defect’ layer within the structure in a precise and controlled manner. This defect layer is obtained by epitaxial growth nominally outside the optimal growth ‘window’. The defect layer can be suitably intermixed to achieve spatially localised increases in the band-gap.

The expression “defect layer” is intended to encompass any epitaxially grown layer (ie. having crystalline structural continuity with an underlying, epitaxially grown, high quality crystal structure) that includes a significantly higher number of inherent defects than the underlying high quality crystal structure that forms the main part of the semiconductor device. Typically, high quality metallo-organic chemical vapour deposition (MOCVD) epitaxy material gives a defect density of <10 defects/cm². By comparison, high quality molecular beam epitaxy (MBE) material gives a defect density of ˜100 defects/cm². In the present invention, the defect layers have a defect density >1000 defects/cm² or >10⁶ defects/cm³.

The expression “defect” is intended to encompass elements in interstitial positions, including those of a dopant material which may be included during epitaxial growth, and generally elements that are not in position in the crystal lattice, as well as vacancies formed in the lattice. By contrast, dopant elements that have been incorporated into proper positions in the crystal structure during epitaxial growth are not generally regarded as “defects” for the purposes of this specification.

FIG. 1 illustrates high quality epitaxial growth of a semiconductor QW well structure 15, suitable for a laser, for example. The epitaxial growth is normally carried out using MBE or MOCVD. The epitaxy structure 16 is grown at optimum conditions, ie. the best ‘growth window’ to obtain the highest quality material for a laser device (in terms of low threshold, high slope efficiency, long lifetime device etc).

In a preferred embodiment, the high quality epitaxy structure is capped during epitaxial growth with a high defect density layer or layers 17. The high defect density layer or layers 17 are grown by changing the epitaxial growth conditions, such as the III-V ratio, to deliberately introduce crystalline defects in a controlled and precise manner. The high density defect layer provides sufficient defect density to allow intermixing to occur.

In a preferred embodiment, the standard (high quality) epitaxy structure 16 is grown or deposited using a source element V-III ratio of close to standard conditions of 1:1, while the defect layer 17 is grown or deposited using a source element V-III ratio lying between standard/2 and standard/20 corresponding to a ratio of 1:0.5 and 1:0.05.

In a more general aspect, for growth of the defect layer 17, the source element ratio is varied from the ideal stoichiometric ratio for a high quality crystal structure to a ratio which increases the defect levels to >1000 defects/cm², or which increases the defect levels by at least a factor of 10, and more preferably by a factor of 100, over those found in the high quality epitaxy structure 16.

FIG. 2 shows a laser structure layer chart as an illustrative example. A 980 nm laser is chosen as the example, but similar arrangements may be used for any individual semiconductor device or device-to-device integration.

The exemplary semiconductor laser consists typically of:

| | | |
|---|---|---|
| a) | n-type GaAs | layer 1 |
| b) | n-type AlGaAs | layers 2, 3 |
| c) | undoped AlGaAs GRINSCH | layer 4 |
| d) | undoped InGaAs QW | layer 5 |
| e) | undoped AlGaAs GRINSCH | layer 6 |
| f) | p-type AlGaAs | layers 7, 8, 9 |
| g) | p-type GaAs | layer 10 |
| h) | p-AlGaAs | layer 11 (the high defect layer) |
| i) | p-GaAs cap layer | layer 12 |

Layers 1-10 are grown under the best possible conditions to obtain the optimum performance from the laser structure and form, in combination, the high quality epitaxy structure 16 (FIG. 1). Preferably, the layers are grown using epitaxial MOCVD and MBE techniques.

The additional layer 11 (which may comprise a series of separate sub-layers) is grown on top of the laser structure 15 as the high defect layer 17. In this case, the high defect layer 11, 17 could be, for example, GaAs, AlGaAs or GaInP. The high defect layer is deposited outside the optimum growth ‘window’ by changing at least one growth parameter, for example the III-V ratio as discussed above. This enhances the introduction of point defects in the layer, such as Ga vacancies. In this manner a high defect density layer is grown on top of the laser structure. Preferably, layer 11 is grown using MOCVD or MBE techniques using a low III-V ratio.

Preferably the laser structure includes layer 12 which is a cap layer to inhibit oxidation.

As shown in FIG. 3, the resulting epitaxy structure 15 can be processed by photolithography and etching of the high defect layer 17 using known methods to spatially define areas 30 of high defect epitaxy 17 on top of high quality epitaxy 16. In preferred device manufacture, these areas 30 would correspond to facet ends of a laser.

With reference to FIG. 4, the sample can be further processed by depositing a layer 40 of SiO₂ over the structure 15, followed by a thermal anneal to allow the high defect material to diffuse into the high quality material intermixing a quantum well region.

The effectiveness of the thermal anneal process is substantially enhanced by the high defect material such that a QWI anneal process can be effected at temperatures less than 850 degrees C. Preferably, the anneal process takes place at temperatures less than 800 degrees C. The annealing process allows the propagation of defects 41 from the ‘high defect’ areas to diffuse into and intermix the QW regions.

FIG. 5 shows a band gap diagram of a laser device 50. In a typical example, the intermixed regions are implemented at the facet ends 51, 53 of the laser 50 to provide non-absorbing mirrors (NAMs), but not implemented in the laser cavity waveguide region 53. This enables the manufacture of high power, long lifetime devices.

This method is not limited to 980 nm laser but any semiconductor laser or semiconductor device that has a QW region and allows improvements in individual devices or the fabrication of photonic circuits that consist of active and passive components on chip.

With reference to FIG. 6, in an alternative embodiment, a defect layer 61 of GaIP or AlGaInP is epitaxially grown onto the high quality epitaxy GaAs structure 60. The defect layer 61 is lattice matched to the underlying GaAs material structure so that the difference in thermal expansion coefficients creates localised strain and hence induces additional defects in the lower layers which can assist quantum well intermixing during thermal treatment. The defect layer 61 may comprise several sub-layers.

Preferably, the thermal treatment for quantum well intermixing is carried out at less than 850 degrees C., and more preferably at less than 800 degrees C.

Similarly, with reference to FIG. 7, a defect layer 71 of GaInAsP lattice matched to a InP material system can achieve a similar effect to that described in connection with FIG. 6. Defect layer 71 may comprise one or more sub-layers (not shown).

The use of quaternary (or quinternary) III-V materials allows the defect energy to be varied over a wider parameter space since there are three (or more) group III elements to vary with respect to the group V element during growth. In a preferred example, the V-III source element ratio is varied between 1:0.5 and 1:0.05. In other examples, the relative ratios of the multiple group III elements to one another may also be varied to achieve varying defect levels, while the group V proportion is maintained at a constant value.

With reference to FIG. 8, in a further arrangement, a strain layer 85 may be incorporated into a defect layer 81 to enhance the dislocation propagation since it is known that the dislocation propagation is directly proportional to the shear stress on the crystal. The strain layer 85 may comprise one or more sub-layers (not shown).

The expression “strain layer” is intended to encompass any substantially single crystal layer having a crystalline structure which differs in terms of lattice constant, periodicity or orientation from an underlying, epitaxially grown, high quality crystal structure to a sufficiently small extent not to substantially interfere with the optical properties of a device to be formed, but sufficient to introduce a number of defects to achieve quantum well intermixing.

The strain layer 85 can be introduced by growing one or more quantum wells in the defect layer 81 that are above the critical thickness. The critical thickness can be understood to be the thickness of strain layer at which lattice constant mismatch between two layers are sufficiently dissimilar that the strain due to the lattice mismatch can no longer be accommodated without creating significant number of defects. In the preferred embodiment, this significant number of defects in >1000 defects/cm². The number of defects will be directly proportional to the amount of lattice mismatch or strain in the system.

Alternatively, it may be possible to introduce a strain layer 85 and/or one or more quantum wells above the critical thickness to nucleate the desired dislocations. In this manner, the dislocation density of the ‘defect’ layer 81 can be controlled, since the dislocation density is a function of strain and alloy composition.

With reference to FIG. 9, a defect layer 91 may be grown upon the high quality epitaxy structure 90 by providing nucleation sources 92 on the surface of the epitaxy structure 90, then growing the defect layer 91 thereover. The nucleation sources 92 may be provided by way of a patterned surface 94, which could be formed using conventional photolithographic techniques. The threading dislocation density can be the dominant misfit dislocation source rather than inherently growing defects into the defect layer by the use of sub-optimal process parameters.

In a further embodiment, the ‘defect’ layer may be purposely phase separated and/or ordered to introduce localised strain into neighbouring layers. For example in an AlGaInP epitaxial growth, the growth conditions can be controlled in such a way that instead of a random alloy of AlGaInP, the AlGaInP phase can separate into atomic ‘strips’ of AlP, GaP, Inp and all the various combinations of the ternary III-V system. This ordering creates defect layers at the interfaces of the ‘strips’.

The defect layer need not be located on the top of the high quality epitaxy structure. It could be incorporated within it at a suitable depth below the surface. With reference to FIG. 10, an epitaxy structure 100 includes a first quantum well 101 and a second quantum well 102, and a defect layer 103 buried within the epitaxy structure. The defect layer 103 may comprise a number of sub-layers.

Defect layers 103 can be located at different depths within the structure to allow intermixing of features in the crystal growth direction as well as across the crystal plane.

With reference to FIG. 11, in a further embodiment the epitaxially grown defect layer 111 on top of the high quality epitaxy structure 110 is highly doped with an impurity in such a manner that, after thermal annealing, the impurity can diffuse into neighbouring layers. An exemplary doped layer is AlGaAs doped with Be. Preferably, the dopant levels lie in the range 10¹⁶ to 10²⁰ cm⁻³ such that QWI effects can be achieved without compromising device performance to an unacceptable degree. While the mobile impurity can cause quantum well intermixing, this technique may also have the disadvantage that the impurity can act as an absorption centre.

With reference to FIG. 12, the defect layer 121 may be grown by changing the temperature of epitaxial growth to introduce the defects into the defect layer 121, providing that the change in temperature used to form the defect layer is not sufficiently large to have a deleterious effect on the performance of the photonic device.

If the temperature window for growth of high quality laser material and the growth of defect layer overlap then there is a clear advantage in using that overlap temperature range for the defect layer growth.

A number of advantages are realised by the use of the foregoing techniques. The use of defect and strain layers formed within the epitaxially grown semiconductor material provides a relative simple and cost-effective method of intermixing a semiconductor structure. Thermal anneal temperatures and surface damage is less than the dielectric method described in the prior art.

Simpler, more reliable, more cost effective and better control of the tuning of the band gap can be obtained. Spatially localised intermixed regions can be obtained in the crystal growth direction as well across the crystal plane.

Other embodiments are intentionally within the scope of the accompanying claims.

1. A method of fabricating a semiconductor device in a semiconductor structure, comprising the steps of:
forming a first, relatively high quality, epitaxial layer on a substrate, the high quality layer including a quantum well;
forming a second, relatively lower quality, epitaxial defect layer on top of the high quality layer; and
thermally processing the structure to effect at least partial diffusion of the defects from the defect layer into the high quality layer in order to achieve quantum well intermixing in the structure.

2. The method of claim 1 in which the high quality epitaxial layer is formed comprising a series of sub-layers.

3. The method of claim 1 in which the defect layer is formed comprising a series of sub-layers.

4. The method of claim 1 further including the step of forming a further high quality epitaxial layer on top of the defect layer prior to the thermal processing step.

5. The method of claim 1 further including the step of forming a cap layer on top of the defect layer.

6. The method of claim 5 in which the cap layer is adapted to inhibit oxidation of the defect layer during subsequent processing.

7. The method of claim 1 in which the defect layer is formed by varying the source element ratio during growth away from ideal or stoichiometric conditions to result in crystalline defects.

8. The method of claim 1 in which the defect layer is formed by varying the substrate temperature away from ideal conditions to result in crystalline defects.

9. The method of claim 7 in which the defect layer comprises a defect density in excess of 1000 defects/cm² or 10⁶ defects/cm/³.

10. The method of claim 7 in which the defect layer comprises a defect density 10 times higher than that of the high quality layer.

11. The method of claim 10 in which the defect layer comprises a defect density 100 times higher than that of the high quality layer.

12. The method of claim 1 in which the semiconductor device is formed in a III-V crystal structure, including the steps of:
providing a V-III source element ratio during growth of the high quality layer of substantially 1:1; and
providing a V-III source element ratio during growth of the defect layer lying between 1:0.5 and 1:0.05.

13. The method of claim 1 further including the step of photolithographically processing the substrate to spatially define areas of the defect layer over the surface of the substrate.

14. The method of claim 13 in which the defect layer is defined over regions of the structure that will form non-absorbing mirrors of a laser device.

15. The method of claim 1 further including the step of depositing a layer of SiO₂ over the defect layer.

16. The method of claim 1 in which the defect layer is provided having a different thermal expansion coefficient than the high quality layer, the layers being lattice matched such that the difference in thermal expansion creates a localized strain increasing defect production during the thermal processing step.

17. The method of claim 16 in which the defect layer includes at least a AlGaInP layer and the high quality layer includes at least a GaAs layer.

18. The method of claim 16 in which the defect layer includes at least a Al GaAs layer and the high quality layer includes at least a GaAs layer.

19. The method of claim 16 in which the defect layer includes at least a GaInAsP layer and the high quality layer includes at least an InP layer.

20. The method of claim 1 further including the step of incorporating a strain layer within the defect layer to enhance dislocation propagation during the thermal processing step.

21. The method of claim 1 in which the thermal processing step is performed at temperatures of less than 850 degrees C.

22. The method of claim 1 wherein the semiconductor device formed comprises any one of a laser, a vertical cavity light emitting device, a passive waveguide, an optical integrated circuit and a photonic integrated circuit.

23. A semiconductor device formed in a semiconductor substrate, comprising:
a first, relatively high quality epitaxial layer formed on the semiconductor substrate to include a quantum well;
a second, relatively lower quality epitaxial layer formed on the high quality epitaxial layer; and
at least a portion of the quantum well in the high quality epitaxial layer becoming a quantum well intermixed region after subjecting the first and second epitaxial layers to a thermal step to diffuse defects from the second epitaxial layer into the first epitaxial layer.

24-25. (canceled)
